(19) United States
(12) Patent Application Publication
(10) Pub. No.: US 2013/0099238 A1
(43) Pub. Date: Apr. 25, 2013

(54) LIQUID CRYSTAL DISPLAY HAVING A HIGH APERTURE RATIO

(71) Applicants: Ming-Yao Chen, Hsin-Chu (TW); Pei-Ming Chen, Hsin-Chu (TW)

(72) Inventors: Ming-Yao Chen, Hsin-Chu (TW); Pei-Ming Chen, Hsin-Chu (TW)

(21) Appl. No.: 13/467,047

(22) Filed: May 9, 2012

(30) Foreign Application Priority Data
Oct. 19, 2011 (TW) 100137854

(51) Int. Cl. H01L 29/786

(52) U.S. Cl. 257/59; 257/E29.273

(57) ABSTRACT

A (liquid crystal display) LCD includes a pixel array and a gate driving circuit. The pixel array includes a plurality of first oxide thin film transistors, a first oxide thin film transistor of the first oxide thin film transistors with a shortest channel length having a first channel length. The gate driving circuit is coupled to the pixel array for driving the pixel array, and includes a plurality of second oxide thin film transistors. The second oxide thin film of the second oxide thin film transistors with a longest channel length has a second channel length. A ratio of the second channel length and the first channel length is greater than 1.5. By limiting the ratio of the second channel length and the first channel length, the aperture ratio of the display panel can be improved without deteriorating the operation stability of the LCD.

### BACKGROUND OF THE INVENTION

1. Field of the Invention

The present invention relates to a liquid crystal display, especially a liquid crystal display with a high aperture ratio.

2. Description of the Prior Art

Displays, such as thin film transistor (TFT) displays, organic light emitting diode (OLED) displays, low temperature poly-Si (LTPS) displays and plasma displays, are widely used nowadays. Please refer to FIG. 1, FIG. 1 shows a prior art display panel 100. The display panel 100 is a TFT LCD panel 100 including a plurality of pixels 112 arranged in a matrix manner. The pixels 112 are controlled by a data driving circuit 114 via a plurality of data lines D₁, D₂, . . . , Dₙ and controlled by a gate driving circuit 116 via a plurality of gate lines G₁, G₂, . . . , Gₘ. Further, the display panel 100 is coupled to a print circuit board (PCB) 118. The circuits on the PCB 118 can transform image signals into voltage signals, and transmit the voltage signals to the data driving circuit 114 via a control bus 120. The circuits on the PCB 118 can also transfer timing signals into voltage signals, and transmit the voltage signals to the gate driving circuit 116 via the control bus 120.

Considering the complexity of design and the cost issue, conventional methods of driving pixels via outer gate driving chips have been replaced by methods of directly forming gate driving circuit structure on display panels. Please refer to FIG. 2. FIG. 2 shows a gate driver on array (GOA) circuit 200 being integrated on the display panel 100. As depicted in FIG. 2, the GOA circuit 200 is coupled to display panel 100 for generating pluses of fixed timing and transmitting the pulses to display panel 100, to turn on and turn off TFTs in pixels. The GOA circuit 200 includes a plurality of signal lines L₁, L₂, L₃ and L₄, a plurality of TFTs T₁, T₂, T₃ and T₄, a capacitor C₁ and a trace W₁. The signal line L₁ is used for transmitting a voltage signal V_{SS}, the signal line L₂ is used for transmitting a start pulse signal Vₛₜ, the signal line L₃ is used for transmitting a complementary clock V_{xclk}, and the signal line L₄ is used for transmitting a clock V_{clk}. The trace W₁ is used for transmitting signals, such as the clock V_{clk} of the signal line L₄, to an inner element, such as TFT T₂.

When designing LCDs, in order to increase contrast and reduce backlight power consumption, high aperture ratios of LCD panels are usually highly concerned. The aperture ratio can be referred to the light penetration ratio. The higher the aperture ratio, the less power the light source will dissipate on the LCD panels, thus more light can be penetrated. So far methods of increasing aperture ratio of panels through reducing the size of elements in the pixel areas of panels have been applied, for example, in FIGS. 1 and 2, the size of transistor elements in pixel 112 can be reduced through shortening the channel length thereof. When the size of transistor elements is reduced, the light penetration area will increase, thus increasing the aperture ratio of the display panel 100.

In order to reduce the frame width of the display panel 100, the size of the GOA circuit 200 is often reduced. It is commonly implemented by shortening the channel length of TFTs on the GOA circuit 200. However this will reduce the stability of the display panel 100. For example, in FIG. 2, the threshold voltage of the TFT T1 will be lowered with the reduction of the channel length of the TFT T1, thus increasing the leakage current IOFF flowing to the TFT T1, causing abnormal function of the circuitry, and deteriorating the stability of the display panel 100.

### SUMMARY OF THE INVENTION

An embodiment of the present invention provides an LCD. The LCD comprises a pixel array and a gate driving circuit. The pixel array comprises a plurality of first oxide thin film transistors. A first oxide thin film transistor of the first oxide thin film transistors with a shortest channel length has a first channel length. The gate driving circuit is coupled to the pixel array for driving the pixel array. The gate driving circuit comprises a plurality of second oxide thin film transistors. A second oxide thin film of the second oxide thin film transistors with a longest channel length has a second channel length. A ratio of the second channel length and the first channel length is greater than 1.5.

Another embodiment of the present invention provides an LCD. The LCD comprises a pixel array and a gate driving circuit. The pixel array comprises a plurality of first oxide thin film transistors, and the first oxide thin film transistors have a first channel length. The gate driving circuit is coupled to the pixel array for driving the pixel array. The gate driving circuit comprises a plurality of second oxide thin film transistors, and the second oxide thin film transistors have a second channel length. A ratio of the second channel length and the first channel length is greater than 1.5.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a prior art display panel.

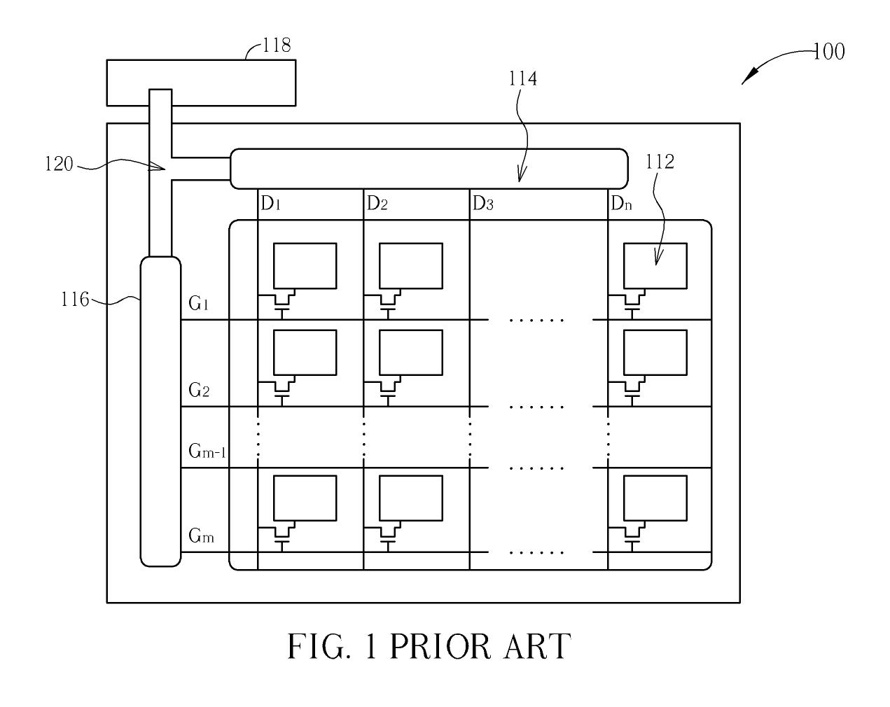

FIG. 2 shows a gate driver on array circuit integrated in the display panel in FIG. 1.

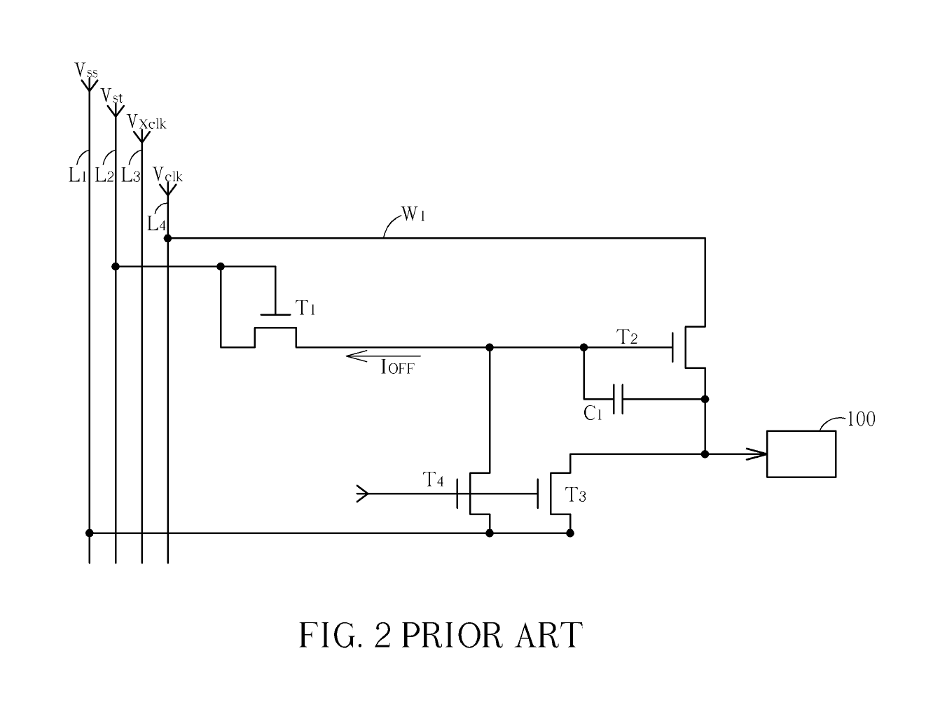

FIG. 3 shows an LCD of the present invention.

### DETAILED DESCRIPTION

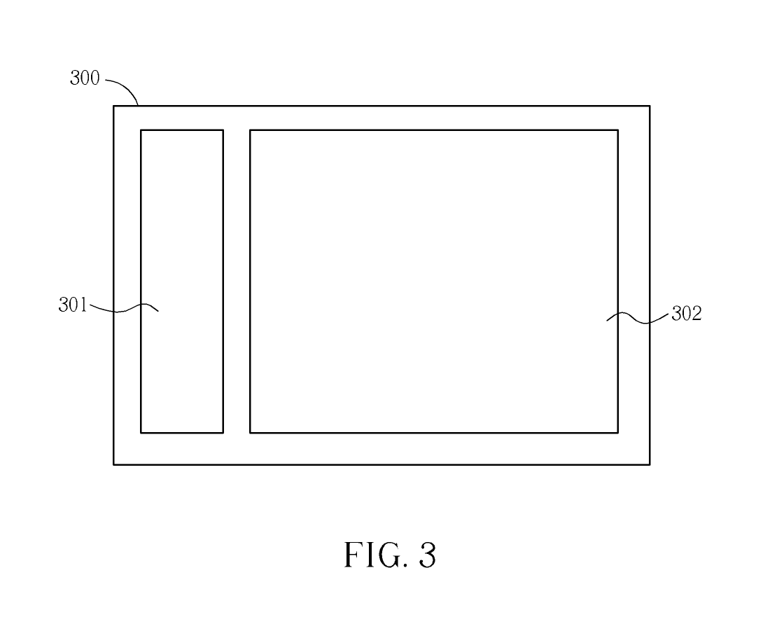

Please refer to FIG. 3. FIG. 3 shows an LCD 300 of the present invention. In the first embodiment of the present invention, the LCD 300 comprises a pixel array 302 and a gate driving circuit 301. The gate driving circuit 301 can be implemented with a gate driver on array (GOA) circuit. The gate driving circuit 301 is coupled to the pixel array 302 for driving the pixel array 302. The pixel array 302 comprises a plurality of first oxide thin film transistors. A first oxide thin film transistor of the first oxide thin film transistors with a shortest channel length has a first channel length. The gate driving circuit 301 comprises a plurality of second oxide thin film transistors. A second oxide thin film transistor of the second oxide thin film transistors with a longest channel length has a second channel length. A ratio of the second channel length and the first channel length is greater than 1.5.

In the second embodiment of the present invention, the LCD 300 comprises a pixel array 302 and a gate driving circuit 301. The gate driving circuit 301 can be implemented with a gate driver on array (GOA). The pixel array 302 comprises a plurality of first oxide thin film transistors, and the first oxide thin film transistors have a first channel length. The gate driving circuit 301 is coupled to the pixel array for driving the pixel array. The gate driving circuit 301 comprises a plurality of second oxide thin film transistors, and the second oxide thin film transistors have a second channel length. A ratio of the second channel length and the first channel length is greater than 1.5.

In the first and the second embodiment of the present invention, the first channel length is essentially between 3 micrometers and 5 micrometers, and the second channel length is essentially greater than 8 micrometers. The threshold voltages of the first oxide thin film transistors and the second oxide thin film transistors become negative with the reduction of the first channel length and the second channel length. That is, the lower the first channel length and the second channel length are, the less voltage is required to turn on the first oxide thin film transistors and the second oxide thin film transistors.

Through the configurations of the first and second embodiments of the present invention that the ratio of the second channel length and the first channel length is greater than 1.5, the channel length of the plurality of the second oxide thin film transistors will not be too short that leads to very low threshold voltages of thin film transistors, causing excessive leakage current flowing to thin film transistors and abnormal function of the circuitry. Therefore, the aperture ratio of the LCD 300 of the present invention can be improved without deteriorating the operation stability of the LCD 300.

In view of above, the present invention limits the ratio of the channel lengths of the oxide thin film transistors of the pixel array and of the gate driving circuit. Therefore, when designing the aperture ratio for LCD panels, the channel length of the thin film transistors of the gate driving circuit will not be configured too short, thus preventing the threshold voltage of the gate driving circuit being too low, deteriorating the operation stability of LCD panels.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A (liquid crystal display) LCD comprising:
a pixel array comprising a plurality of first oxide thin film transistors, a first oxide thin film transistor of the first oxide thin film transistors with a shortest channel length having a first channel length; and
a gate driving circuit coupled to the pixel array for driving the pixel array, the gate driving circuit comprising a plurality of second oxide thin film transistors, a second oxide thin film of the second oxide thin film transistors with a longest channel length having a second channel length, a ratio of the second channel length and the first channel length being greater than 1.5.

2. The LCD of claim 1, wherein smaller channel widths of the first oxide thin film transistors and the second oxide thin film transistors correspond to more negative threshold voltages of the first oxide thin film transistors and the second oxide thin film transistors.

3. The LCD of claim 1, wherein the gate driving circuit is a gate driver on array (GOA) circuit.

4. The LCD of claim 1, wherein the first channel length is between 3 micrometers and 5 micrometers.

5. The LCD of claim 1, wherein the second channel length is greater than 8 micrometers.

6. A (liquid crystal display) LCD comprising:
a pixel array comprising a plurality of first oxide thin film transistors, the first oxide thin film transistors having a first channel length; and
a gate driving circuit coupled to the pixel array for driving the pixel array, the gate driving circuit comprising a plurality of second oxide thin film transistors, the second oxide thin film transistors having a second channel length, a ratio of the second channel length and the first channel length being greater than 1.5.

7. The LCD of claim 6, wherein smaller channel widths of the first oxide thin film transistors and the second oxide thin film transistors correspond to more negative threshold voltages of the first oxide thin film transistors and the second oxide thin film transistors.

8. The LCD of claim 6, wherein the gate driving circuit is a gate driver on array (GOA) circuit.

9. The LCD of claim 6, wherein the first channel length is between 3 micrometers and 5 micrometers.

10. The LCD of claim 6, wherein the second channel length is greater than 8 micrometers.
